(19) United States
(12) Patent Application Publication
(10) Pub. No.: US 2020/0287579 A1
(43) Pub. Date: Sep. 10, 2020

(54) RINGING SUPPRESSION CIRCUIT

(71) Applicant: DENSO CORPORATION, Kariya-city (JP)

(72) Inventors: Takuya HONDA, Kariya-city (JP); Tomohisa KISHIGAMI, Kariya-city (JP)

(21) Appl. No.: 16/878,673

(22) Filed: May 20, 2020

Related U.S. Application Data
(63) Continuation of application No. PCT/JP2018/038667, filed on Oct. 17, 2018.

(30) Foreign Application Priority Data
Dec. 25, 2017 (JP) 2017-247635

(51) Int. Cl. H04B 1/04; H03K 17/16

(52) U.S. Cl. CPC H04B 1/0475; H04L 12/40; H03K 17/16

(57) ABSTRACT

A control unit of a suppression circuit turns on an inter-line switching element and maintains an ON state upon detection of a change in the level of a differential signal from high level to low level, and cancels the ON state after a predetermined period of time is measured. A continuous activation prevention unit sets a predetermined mask time period from the time of turning on the inter-line switching element, and masking is performed to prevent the control unit from detecting a change in the level of the differential signal from the high level to the low during the mask time period.

### CROSS REFERENCE TO RELATED APPLICATION

The present application is a continuation application of International Patent Application No. PCT/JP2018/038667 filed on Oct. 17, 2018, which designated the United States and claims the benefit of priority from Japanese Patent Application No. 2017-247635 filed on Dec. 25, 2017. The entire disclosures of all of the above applications are incorporated herein by reference.

### FIELD

The present disclosure relates to a ringing suppression circuit connected to a transmission line that transmits a differential signal.

### BACKGROUND

In case of transmitting a digital signal via a transmission line, a part of a signal energy may be reflected at time when a signal level changes in a receiving side, and hence waveform distortion such as overshoot or undershoot, that is, ringing may occur in the signal. Various techniques for suppressing waveform distortion have been proposed.

For example, it is proposed to match impedances for reducing ringing by turning on an FET connected to a transmission line fixedly for a predetermined time period, when a signal on the transmission line changes from dominant to recessive in CAN communication.

### SUMMARY

According to the present disclosure, a ringing suppression circuit is connected to a transmission line to suppress ringing caused by the transmission line transmitting a differential signal, which varies between a high level and a low level. The transmission line includes a pair of signal lines including a high potential signal line and a low potential signal line. The ringing suppression circuit comprises an inter-line switching element and a control unit. The inter-line switching element is connected between the pair of signal lines. The control unit turns on the inter-line switching element to fix an ON state when detecting that the differential signal has changed from the high level to the low level, and releases the ON state after measuring a predetermined ON time period.

### BRIEF DESCRIPTION OF THE DRAWINGS

The present disclosure will become more apparent from the following detailed description with reference to the attached drawings. In the drawings:

FIG. 1 is a circuit diagram illustrating a configuration of a ringing suppression circuit according to a first embodiment;

FIG. 2 is a time chart showing an operation of the first embodiment;

FIG. 3 is a time chart (part 1) showing an end time of a mask time period;

FIG. 4 is a time chart (part 2) showing an end time of a mask time period;

FIG. 5 is a time chart (part 3) showing an end time of a mask time period;

FIG. 6 is a time chart (part 4) showing an end time of a mask time period;

FIG. 7 is a circuit diagram illustrating a configuration of a ringing suppression circuit according to a second embodiment;

FIG. 8 is a time chart showing an operation of the second embodiment;

FIG. 9 is a circuit diagram illustrating a configuration of a ringing suppression circuit according to a third embodiment;

FIG. 10 is a time chart of an operation of the third embodiment;

FIG. 11 is a circuit diagram illustrating a configuration of a ringing suppression circuit according to a fourth embodiment;

FIG. 12 is a circuit diagram illustrating a configuration of a ringing suppression circuit according to a fifth embodiment;

FIG. 13 is a circuit diagram illustrating a configuration of a ringing suppression circuit according to a sixth embodiment;

FIG. 14 is a circuit diagram illustrating a configuration of a ringing suppression circuit according to a seventh embodiment;

FIG. 15 is a circuit diagram illustrating a configuration of a ringing suppression circuit according to an eighth embodiment;

FIG. 16 is a schematic diagram showing a connection state of two communication nodes in a conventional circuit; and

FIG. 17 is a time chart showing an operation of the conventional circuit.

### DETAILED DESCRIPTION OF THE EMBODIMENT

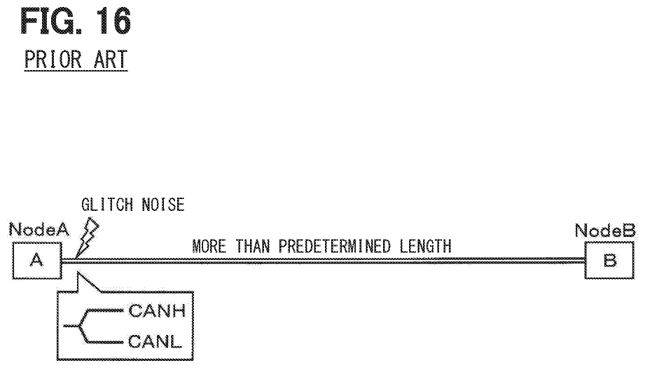

A ringing suppression circuit according to the present disclosure is directed to a communication network. For example, the network is formed with a plurality of communication nodes including the conventional ringing suppression circuit. In this example, as shown in FIG. 16, a length of a communication line is equal to or longer than a certain value. As a result, when a differential signal instantaneously changes to recessive because of application of glitch noise at the time of indicating dominant at a communication node A, a ringing suppressing operation is performed in the communication node A. Then, the signal waveform is distorted by the ringing suppressing operation.

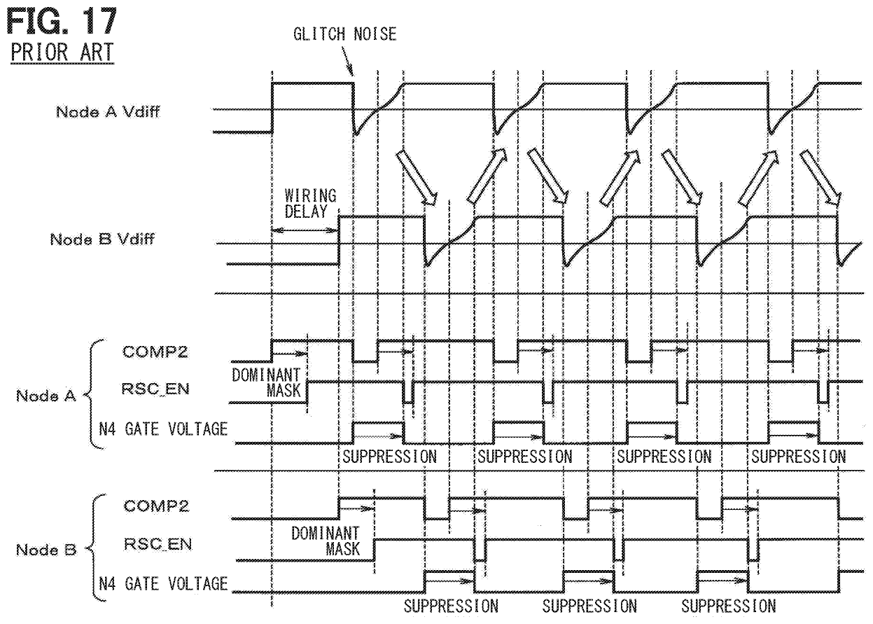

As shown in FIG. 17, because the signal having the distorted waveform arrives at another communication node B with a delay corresponding to a wiring delay, the ringing suppressing operation is also performed at the communication node B. The signal of the waveform distorted by the ringing suppressing operation reaches the original communication node A again. As described above, the transmission of the distorted waveform signal is repeated between the communication nodes A and B, and hence the distortion of the waveform does not converge thereby causing a communication error.

The present disclosure provides various embodiments, which solve the above problems caused by glitch noise.

### First Embodiment

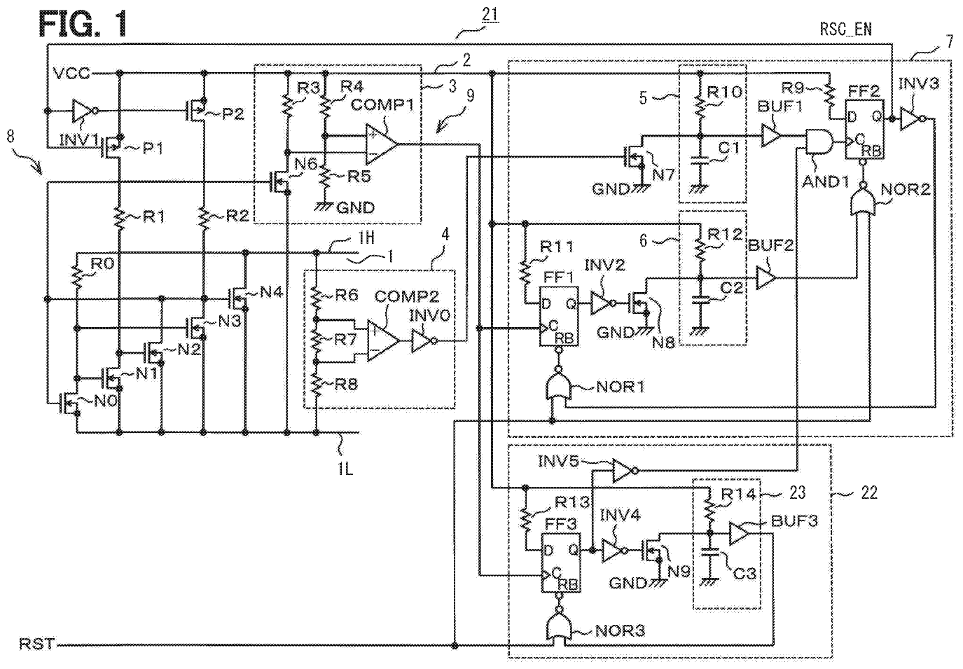

Referring to FIG. 1, a ringing suppression circuit 21 is provided with a continuous activation prevention circuit 22. The ringing suppression circuit 21 is conventional as disclosed in US 2018/0367127A (JP 2017-63399A), which is incorporated herein by reference for simplification of description.

As disclosed in US 2018/0367127A, the ringing suppression circuit 21 is configured to suppress ringing caused in a transmission line 1 transmitting a differential signal using a pair of signal lines including a high potential signal line 1H and a low potential signal line 1L. The differential signal varies between a high level and a low level. The ringing suppression circuit 21 includes, as main components, an FET N4 that is connected as an inter-line switching element between the pair of signal lines 1H and IL n that is, and a control unit 9 that turns on the inter-line switching element N4 to fix the ON state when detecting that the differential signal has changed from the high level to the low level, and releases the ON state after measuring a predetermined ON time period.

The continuous activation prevention circuit 22 has the similar configuration as the configuration of an ON hold circuit 7 which includes a D flip-flop FF1. The continuous activation prevention circuit 22 specifically includes a D flip-flop FF3, an inverter gate INV4, an N-channel MOSFET N9, a buffer BUF3, a NOR gate NOR3, and a series circuit of a resistance element R14 and a capacitor C3. The series circuit forms a delay circuit 23. However, an output terminal of the buffer BUF3 is connected to one of input terminals of the NOR gate NOR3. A clock terminal C of the D flip-flop FF3 is connected to an output terminal of a comparator COMP1 of an ON confirmation circuit 3.

A NOT gate INV5 and an AND gate AND1 are connected between an output terminal of a buffer BUF1 and a clock terminal C of a D flip-flop FF2. An output terminal Q of the D flip-flop FF3 is connected to one of input terminals of the AND gate AND1, and outputs a high active mask signal. The AND gate AND1 may be provided in the continuous activation prevention circuit 22. The delay circuit 23 is provided as a reset signal generation unit, and the AND gate AND1 is provided as a logic gate.

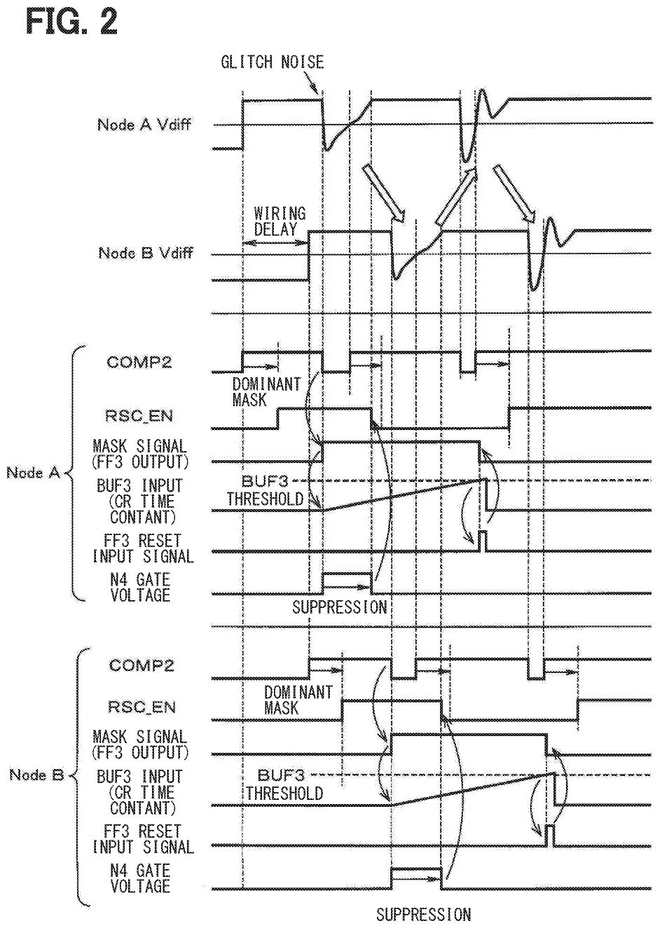

Next, an operation of the present embodiment will be described. As shown in FIG. 2, at a communication node A, an output signal of a comparator COMP2 of a comparison circuit 4 becomes high level at the time of a rising edge of the differential signal applied between the lines 1H and 1L. From this time point, a signal RSC_EN output from a D flip-flop FF2 becomes high level after a predetermined dominant mask time period has elapsed due to a delay operation of a delay circuit 5.

Here, as in the prior art case shown in FIG. 17, it is assumed that glitch noise is applied when the differential signal indicates dominant at the communication node A. Then, gates of FETs N1 and N3 connected to the signal line through a resistance element R0 become low level, and the FETs N1 and N3 are turned off. At this time, an FET P2 is in the ON state, and hence gates of FETs N1, N4 and N6 become high level via a resistance element R2 and these FETs N1, N4 and N6 are turned on. A gate, a source and a drain of an FET is a conduction control terminal, a potential reference side conductive terminal and a non-potential reference side conductive terminal, respectively.

A comparator COMP1 of the ON confirmation circuit 3 becomes high level, and the D flip-flops FF1 and FF3 are triggered. As a result, the D flip-flop FF3 outputs a mask signal of a predetermined mask time period. When the mask signal is the high level, the FET N9 is turned off and charging of the capacitor C3 is started. As a result, a signal level of an input terminal of the buffer BUF3 increases.

When the output terminal of the buffer BUF3 becomes high level, the D flip-flop FF3 is reset via the NOR gate NOR3, and the mask signal becomes low level. While the mask signal output from the D flip-flop FF3 is the high level, the D flip-flop FF2 is not triggered via the AND gate AND1 even if the differential signal changes to the recessive level while indicating the dominant. Therefore, the ringing suppression operation is not reactivated.

The above-described operation of the ringing suppression circuit 21 in the communication node A is also performed in a communication node B after a propagation delay time period associated with a wiring length of a wiring connecting the communication nodes A and B has elapsed. As a result, an application of the glitch noise on the communication node A side causes the ringing suppression operation to be performed only once in each of the communication nodes A and B. Although a signal waveform is distorted because of the ringing suppression operation, transmission of the signal having the distorted waveform as in the prior art is not repeated.

An end time of a mask time period predetermined by setting the delay time in the delay circuit 23 is set to a time period, which is at least 1-bit length of a signal data from a reference time of change of the differential signal from dominant to recessive but less than a period {(2-bit length)−(dominant mask period)} determined by subtracting the dominant mask period from 2-bit length of the signal data. This can prevent the ringing suppression operation from being performed when noise is superimposed during a period when the differential signal indicates recessive.

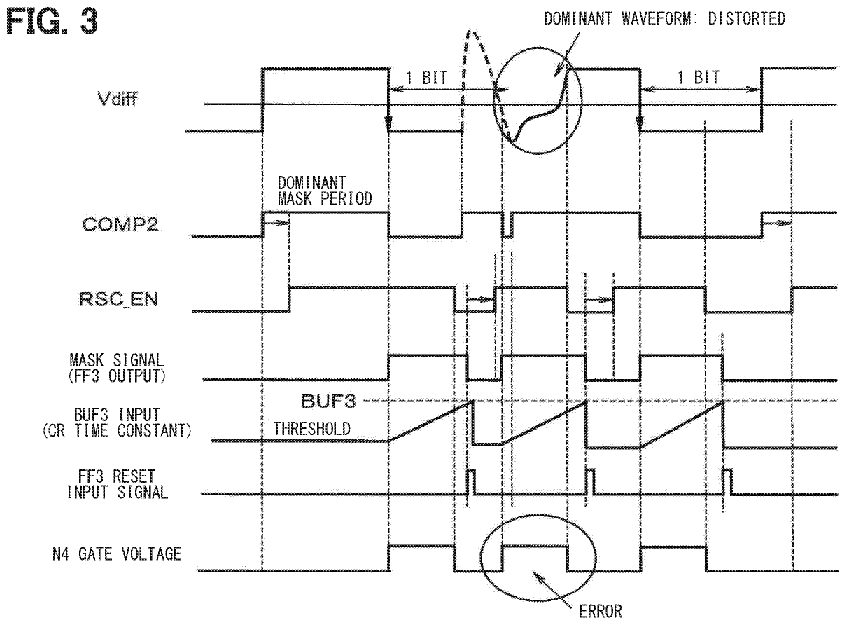

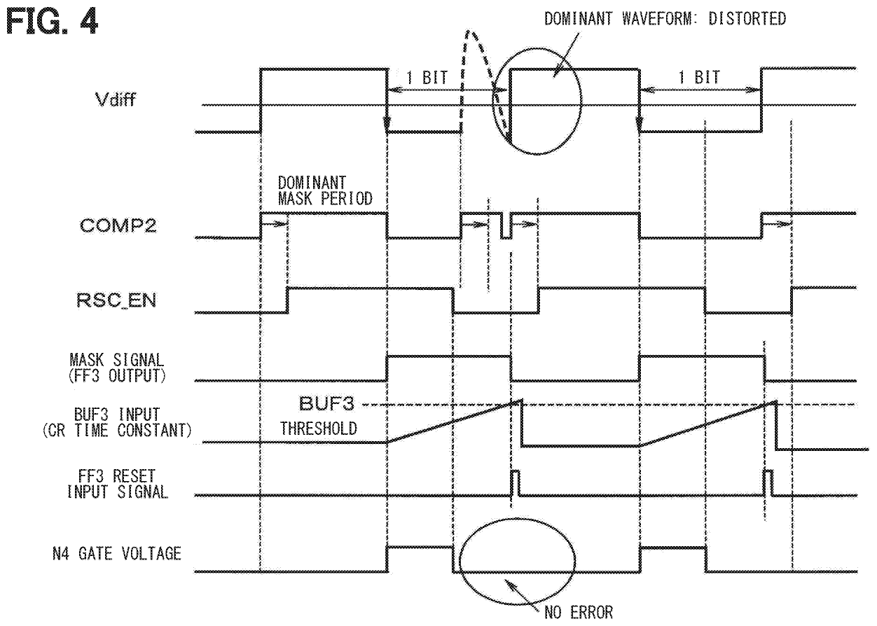

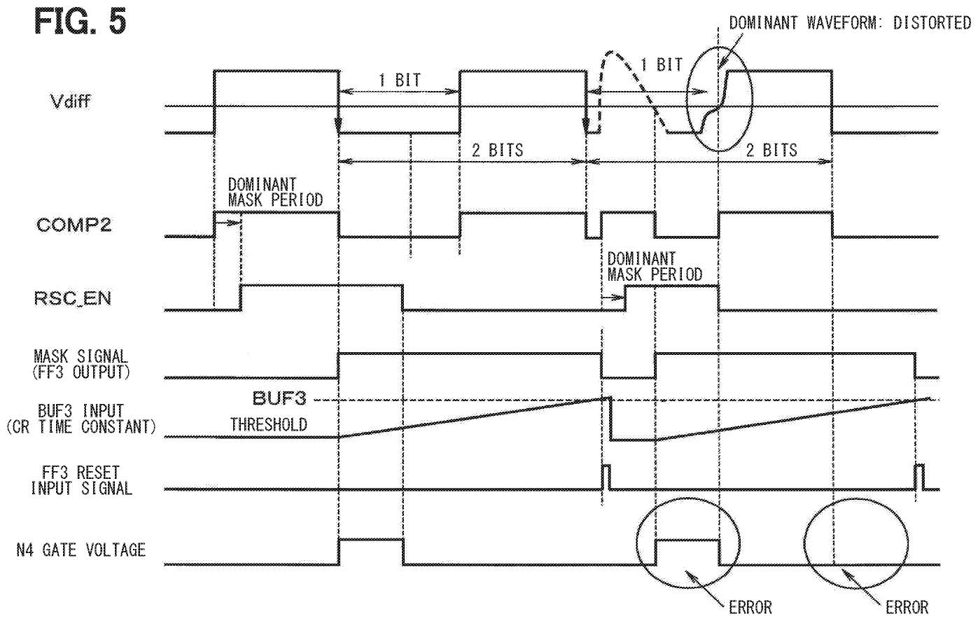

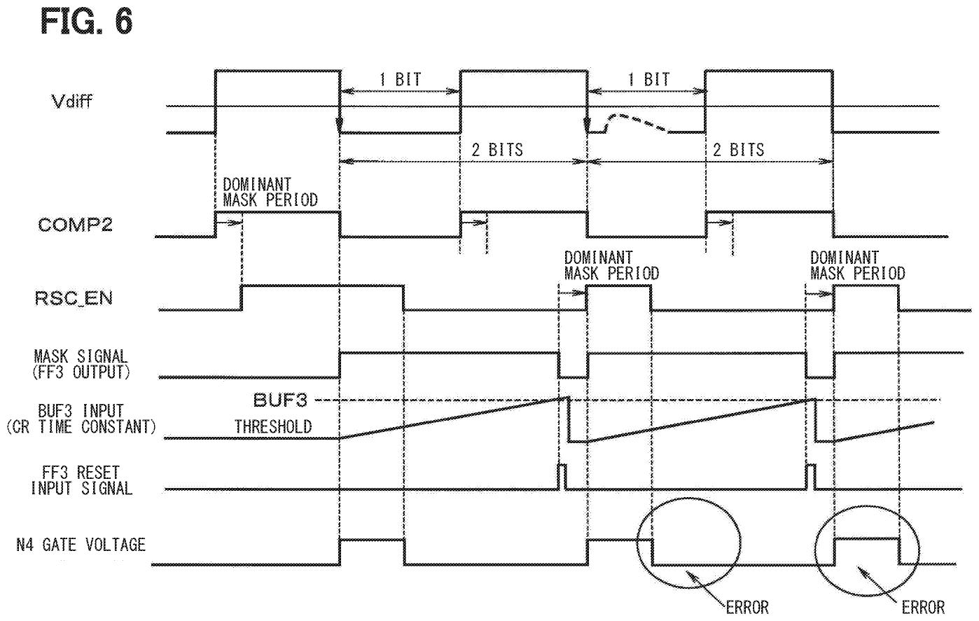

As shown in FIG. 3 and FIG. 4, by setting the end time of the mask time period to be 1-bit length or more from the reference time, operation error (malfunction) in the recessive period immediately after the reference time is prevented. Also, as shown in FIG. 5 and FIG. 6, by setting the end time to be less than {(2-bit length)−(dominant mask time period)} from the reference time, malfunction in the recessive period arriving two bits after the reference time is prevented. If the dominant mask time period is not set, a maximum value at the end of the mask time period may be set to be less than 2 bits.

As described above, according to the present embodiment, when detecting that the differential signal transmitted on the transmission line 1 has changed from dominant to recessive, the control unit 9 turns on the FET N4 to fix its state, and the ON state is released after a predetermined time period is measured by the delay circuit 6. The continuous activation prevention circuit 22 sets the predetermined mask time period from the time of turning on the FET N4, and performs masking to prevent the control unit 9 from detecting the change in the level of the differential signal from high to low during the mask time period.

More specifically, the continuous activation prevention unit 22 is configured by the D flip-flop FF3, the delay circuit 23 and the AND gate AND1. The D flip-flop FF3 is reset in the initial state, and outputs the mask signal for setting the mask time period when set in correspondence to setting of the D flip-flop FF1. The delay circuit 23 resets the D flip-flop FF3 when a time corresponding to the mask time period elapses after the D flip-flop FF3 has been set. The AND gate AND1 invalidates the signal that sets the D flip-flop FF2 by the mask signal.

With this configuration, the control unit 9 does not detect the change even when glitch noise that changes instantaneously and recessively is applied in the state where the differential signal indicates dominant. Therefore, unlike the prior art, it is possible to prevent the ringing suppression operation from being alternately performed between the communication nodes A and B and prevent the distortion of the signal waveform from being continuously generated.

Further, the end time point of the mask time period is set to be equal to or more than 1-bit length of the signal data and less than {(2-bit length)−(dominant mask time period)} from the reference time point when the level of the differential signal changes from dominant to recessive. As a result, it is possible to reliably prevent a malfunction during the recessive period immediately after the reference time and two bits after the reference time.

As disclosed in US 2018/0367127A, the control unit 9 is configured by a D flip-flop FF1, a D flip-flop FF2, an ON confirmation circuit 3, a comparison circuit 4, a delay circuits 5, 6, an FET N7, an ON setting unit 8 and the like. The D flip-flop FF1, the D flip-flop FF2, the delay circuits 5, 6 and the like form an ON hold circuit 7. The D flip-flop FF1 outputs a signal for resetting the D flip-flop FF2 when it is set. The delay circuit 6 is connected between an output terminal Q of the D flip-flop FF1 and a reset terminal RB of the D flip-flop FF2. The comparison circuit 4 outputs a signal for setting the D flip-flop FF2 when detecting that the differential signal has changed from recessive to dominant. The ON confirmation circuit 3 outputs a signal to set the D flip-flop FF1 when detecting that the FET N4 has turned on. The ON setting unit 8 enables a gate of the FET N4, which is the inter-line switching element, to become ON level when the D flip-flop FF2 is set to generate the signal RSC-EN. In the first embodiment, the D flip-flops FF2, FF1 and FF3 are provided as a first flip-flop, a second flip-flop and a third flip-flop, respectively.

Further, the ON confirmation circuit 3 includes an FET N6. A drain of the FET N6 is connected to a power supply line 2 via a resistance element R3. A source and a gate of the FET N6 are connected to a source and a gate of the FET N4, respectively. The ON setting unit 8 has FETs NO to N3 as first to fourth switching elements, FET P1 and FET P2 as fifth and sixth switching elements. Sources of the FETs NO to N3 are connected to the low potential side signal line 1L of the transmission line 1. A source of the FET P1 is connected to the power supply line 2. A drain of the FET P1 is connected to a drain of the FET N1 and a gate of the FET N2 via a resistance element R1. A source of the FET P2 is connected to the power supply line 2. A drain of the FET P2 is connected to a drain of the FET N3 and a gate of the FET N1 via a resistance element R2.

A gate of the FET NO is connected to a gate of the FET N4. Gates of the FET N1 and N3 are connected to a drain of the FET NO and to the high potential side signal line 1H of the transmission line 1 via the resistance element R0. The gate of the FET N2 is connected to the drain of the FET N1. When the D flip-flop FF2 is set, the FET P1 is turned on and the FET P2 is turned off.

When the delay circuit 5 detects that the level of the differential signal has changed from recessive to dominant, the delay circuit 5 delays the set signal of the D flip-flop FF2 output via the FET N7 by the comparison circuit 4, thereby masking the detection of the level change of the differential signal by the control unit 9 for the predetermined period of time (dominant mask period).

### Second Embodiment

Hereinafter, the same components and functions as those in the first embodiment will be designated by the same reference numerals in the following embodiments, and explanations thereof will be simplified. Only differences from the first embodiment will be described.

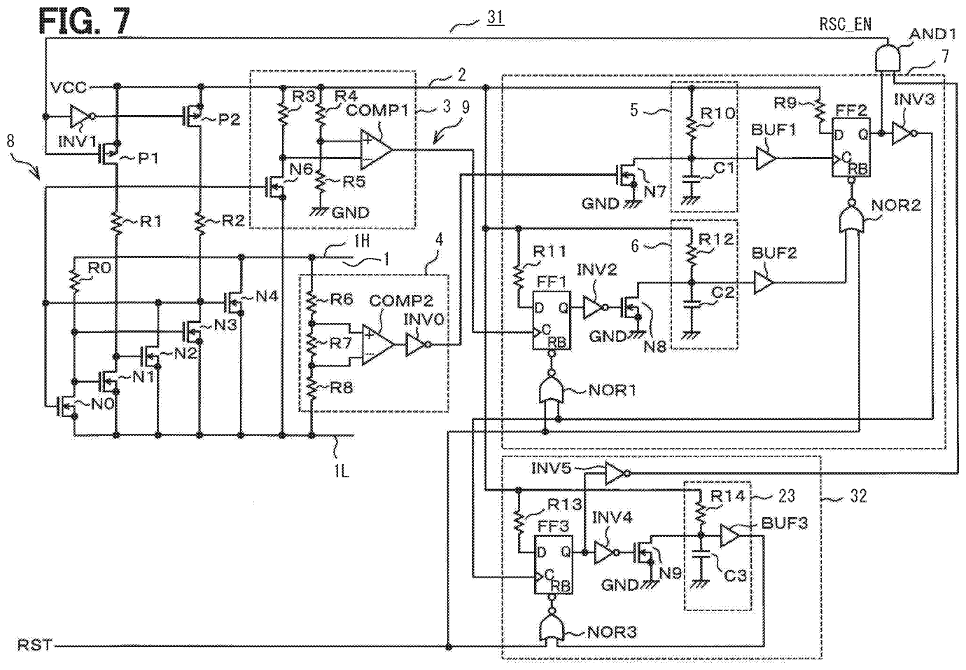

In a second embodiment, as shown in FIG. 7, a ringing suppression circuit 31 of the second embodiment is configured such that one of the input terminals of the AND gate AND1 constituting a part of a continuous activation prevention circuit 32 is connected to the output terminal Q of the D flip-flop FF2. The clock terminal C of the D flip-flop FF3 is connected to the output terminal of the NOT gate INV3. The signal RSC_EN output from the D flip-flop FF2 is output via the AND gate AND1.

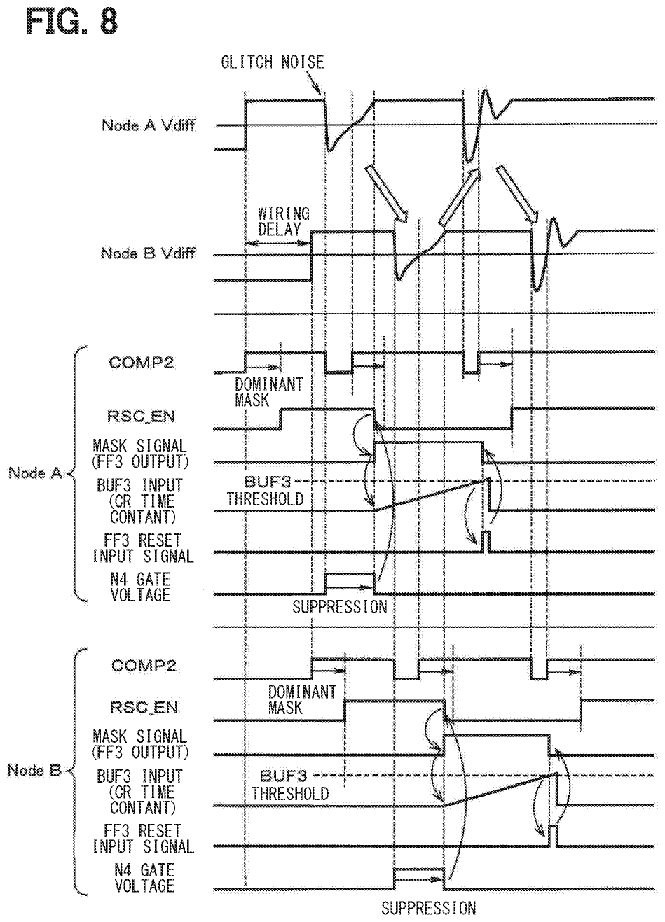

Operation of the second embodiment will be described next. In the initial state, the output terminal Q of the D flip-flop FF3 is at the low level. Therefore, as shown in FIG. 8, when the differential signal changes from dominant to recessive, the signal RSC_EN output from the D flip-flop FF2 rises at the same time as in the first embodiment. When the D flip-flop FF2 is reset and the signal RSC_EN falls, the D flip-flop FF3 is triggered and the mask signal rises. Therefore, the rising timing is later than in the first embodiment.

As described above, according to the second embodiment, the continuous activation prevention circuit 32 is provided with the D flip-flop FF3, the delay circuit 23, and the AND gate AND1 for invalidating the signal, by which the D flip-flop FF2 is set, by the mask signal. Thereby, the same effect as in the first embodiment can be provided.

### Third Embodiment

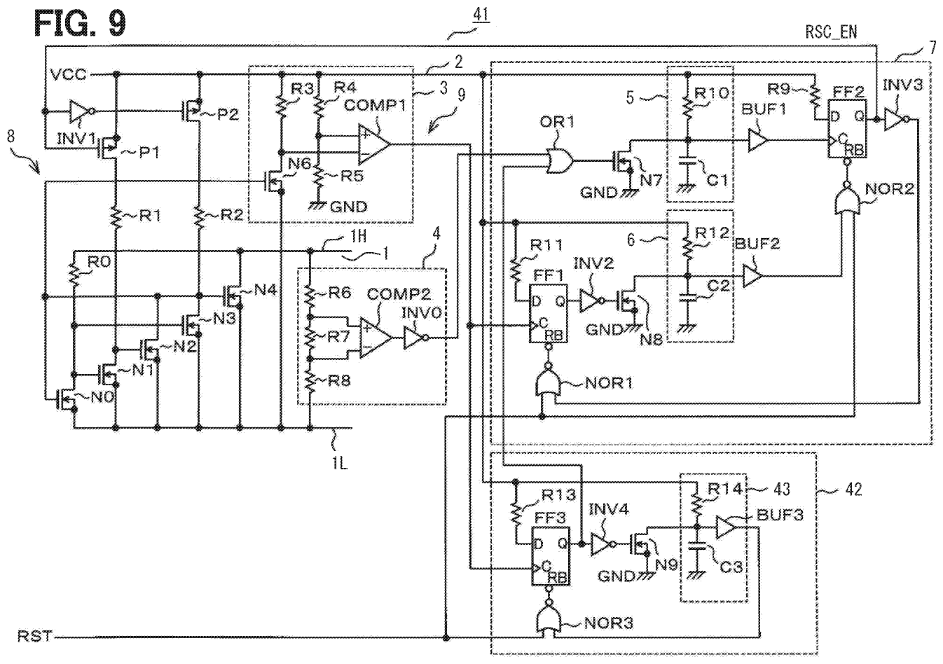

As shown in FIG. 9, a ringing suppression circuit 41 of a third embodiment includes a continuous activation prevention circuit 42. The continuous activation prevention circuit 42 has no NOT gate INV5 of the continuous activation prevention circuit 22 of the first embodiment and the second embodiment, and uses an OR gate OR1 in the ON hold circuit 7 instead of the AND gate AND1. The OR gate OR1 is arranged between the output terminal of the NOT gate INV0 of the comparison circuit 4 and the gate of the FET N7.

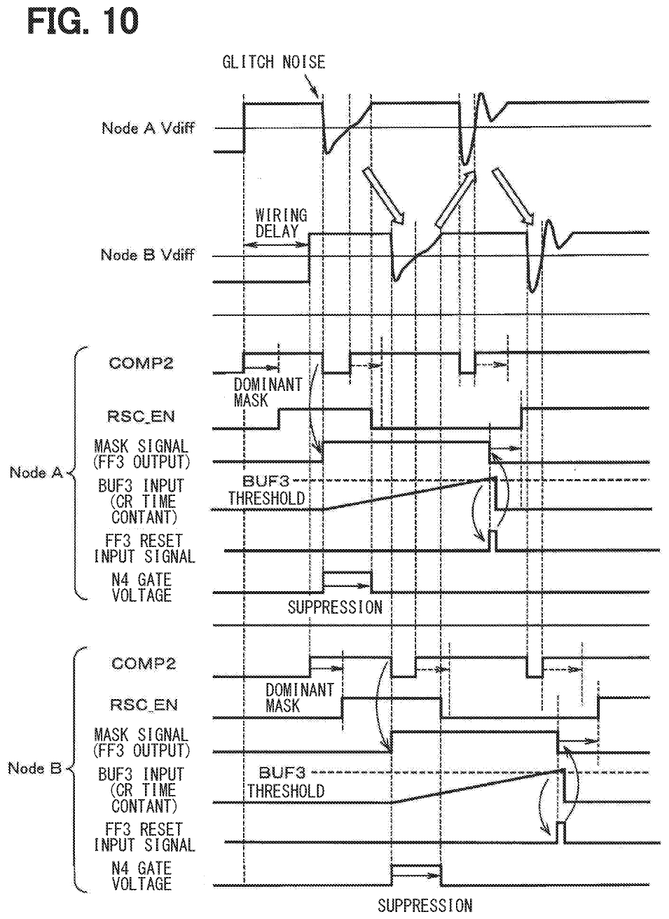

Next, operation of the third embodiment will be described. As shown in FIG. 10, the mask signal rises at the same time as in the first embodiment. Then, when the output signal of the comparator COMP2 changes to the low level next time, the mask signal changes to the high level, so that the output signal of the OR gate OR1 maintains the high level. This masks that the D flip-flop FF2 is triggered. Therefore, the delay time period of a delay circuit 43 is set longer than in the first embodiment.

As described above, according to the third embodiment, the OR gate OR1 of the continuous activation prevention circuit 42 is provided between the NOT gate INV0 of the comparison circuit 4, which is the preceding stage of the D flip-flop FF2, and the FET N7. Thereby, the same effect as in the first embodiment can be provided.

### Fourth to Eighth Embodiments

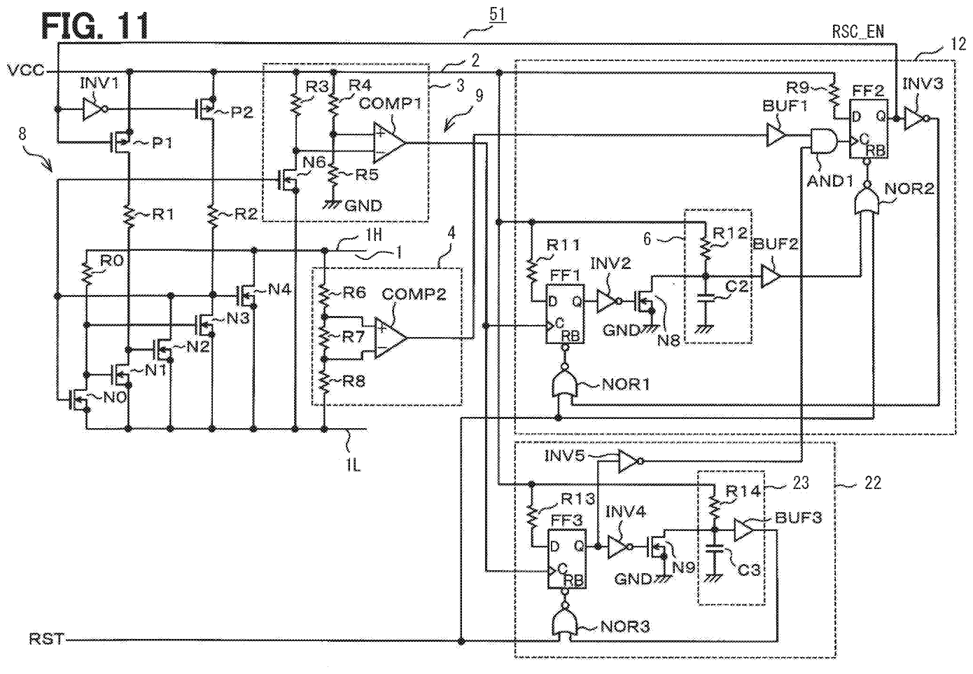

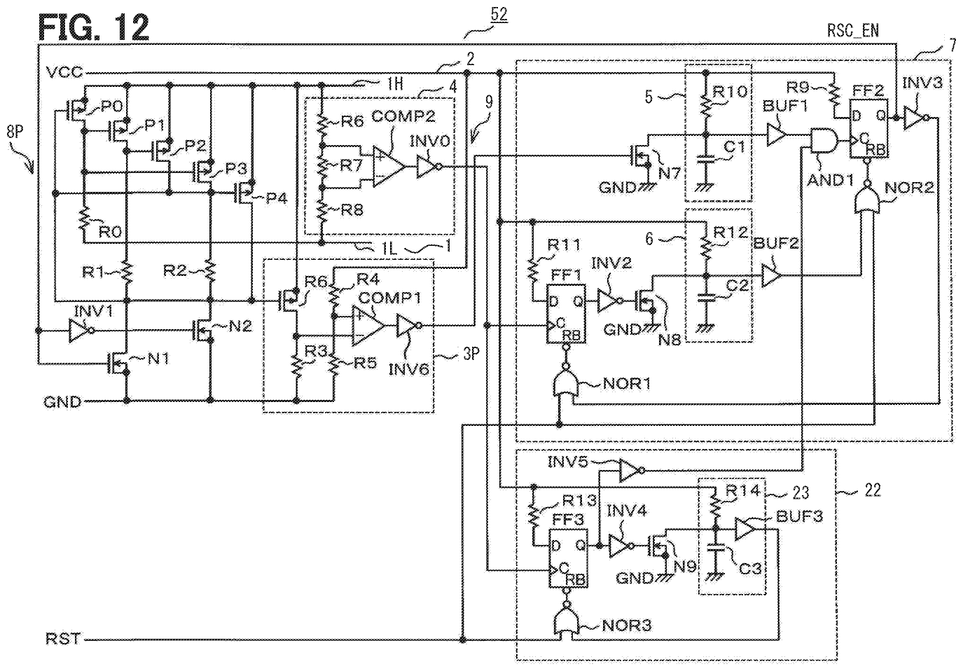

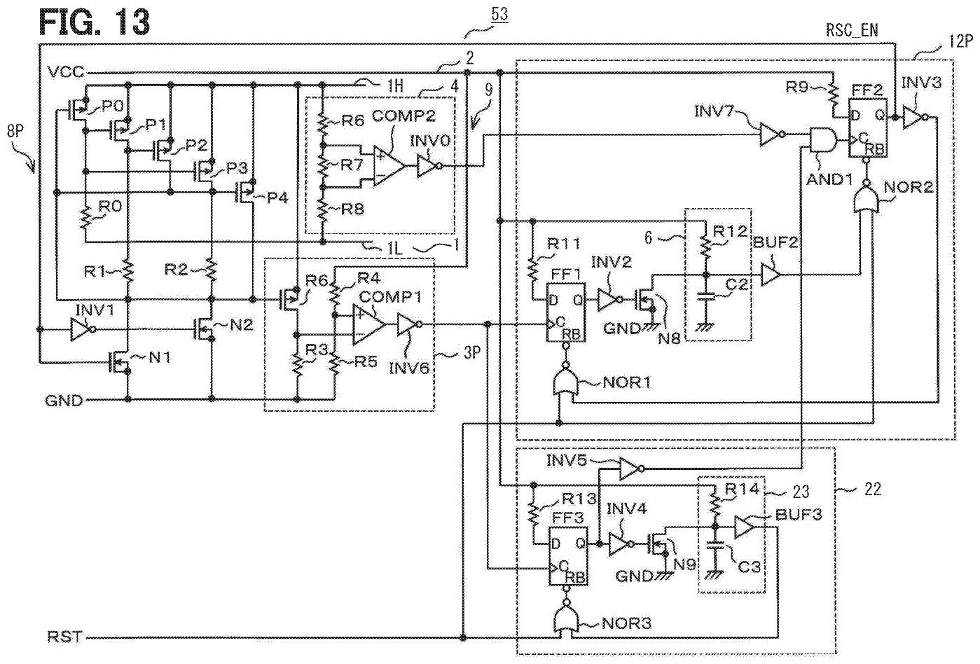

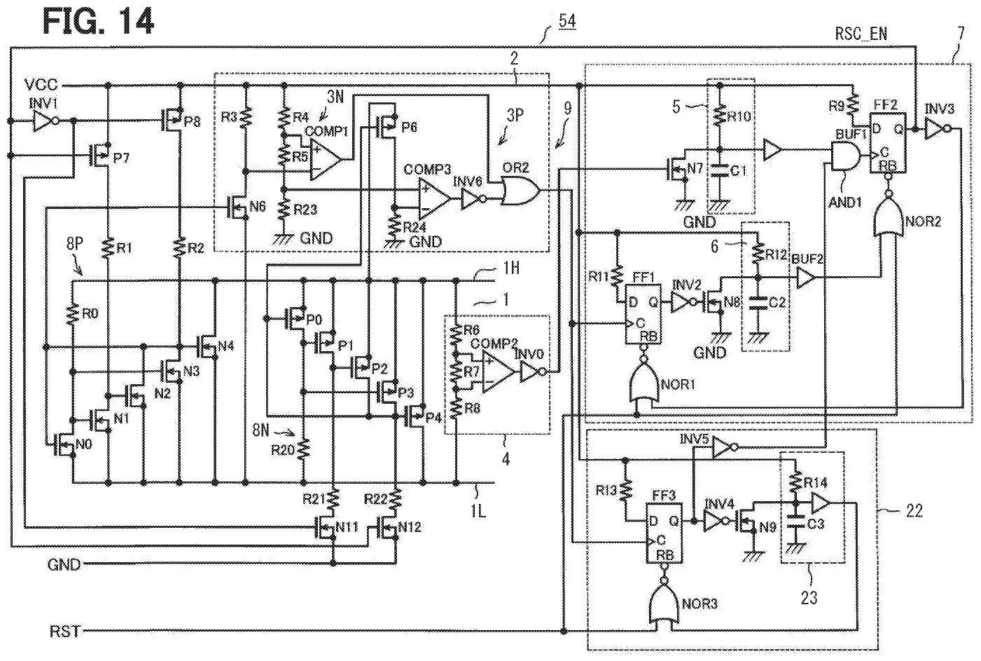

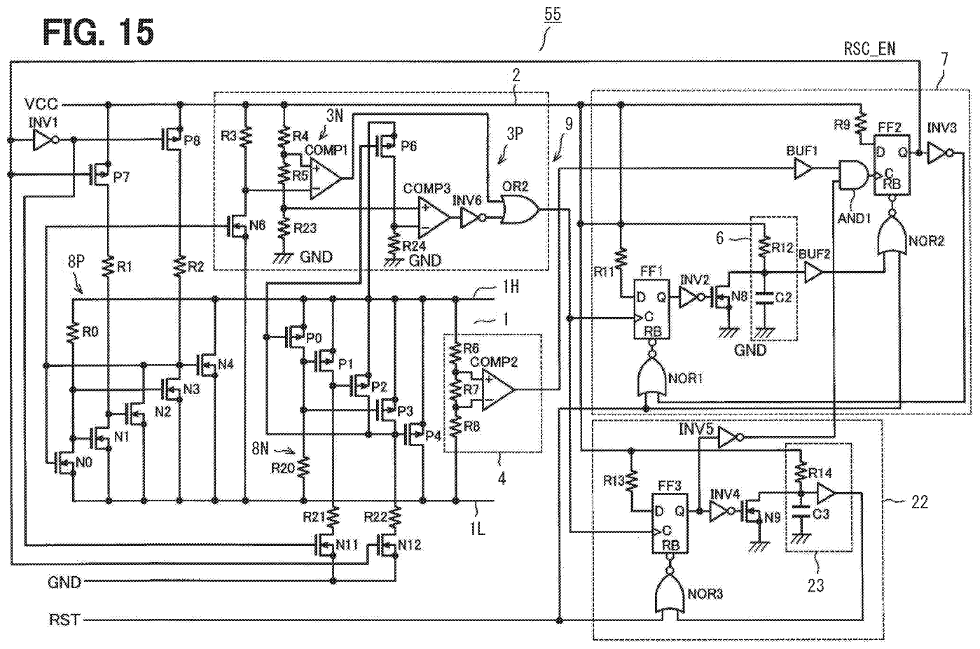

FIG. 11 to FIG. 15 show fourth to eighth embodiments. These ringing suppression circuits 51 to 55 are configured by adding the continuous activation prevention circuit 22 of the first embodiment described above to the ringing suppression circuits 11 and 13 to 16 of the second to sixth embodiments of the ringing suppression circuits disclosed in US 2018/0367127A, which is incorporated herein by reference. It is noted in FIG. 11 to FIG. 15 the reference numerals are changed as follows.

The NOT gates INV4 and INV5 connected to the comparator COMP1 in the third to sixth embodiments are changed to INV 6. The NOT gate INV4 of the fourth embodiment is changed to INV7. The OR gate OR1 of the fifth and sixth embodiments is changed to OR1.

### Other Embodiment

A maximum value of the end of the mask time period is not limited to be set at least 1-bit length from the reference time and less than {(2-bit length)−(dominant mask time period)}.

Instead of the continuous activation prevention circuit 22 of the first embodiment, the continuous activation prevention circuit 32 or 42 of the second or third embodiment may be applied to the fourth to eighth embodiments.

The delay circuits 5, 6, 23 and 43 are not limited to those configured by a resistance element and a capacitor, but may be configured by, for example, a combination with a constant current source.

The resistance elements R1, R2, R21 and R22 may be replaced with a constant current source.

Although the present disclosure has been made in accordance with the embodiments, it is understood that the present disclosure is not limited to such embodiments and configurations. The present disclosure covers various modification examples and equivalent arrangements. In addition, various combinations and forms, and further, other combinations and forms including only one element, or more or less than these elements are also within the scope and the scope of the present disclosure.

What is claimed is:

1. A ringing suppression circuit connected to a transmission line to suppress ringing caused by the transmission line transmitting a differential signal using a pair of signal lines, the differential signal varying between a high level and a low level, the pair of signal lines including a high potential signal line and a low potential signal line, the ringing suppression circuit comprising:
an inter-line switching element that is connected between the pair of signal lines;
a control unit for turning on the inter-line switching element to fix an ON state when detecting that the differential signal has changed from the high level to the low level, and releasing the ON state after measuring a predetermined ON time period; and
a continuous activation prevention unit for setting a predetermined mask time period from time of turning on the inter-line switching element by the control unit, and masking the control unit not to detect a change of the differential signal from the high level to the low level during the predetermined mask time period.

2. The ringing suppression circuit according to claim 1, wherein:
the continuous activation prevention unit sets an end time to be at least 1-bit length and less than 2-bit length of a signal data from time of the change of the differential signal from the high level to the low level.

3. The ringing suppression circuit according to claim 1, wherein the control unit includes:
a first flip-flop, which is reset in an initial state;
a second flip-flop, which is reset in an initial state and outputs a signal for resetting the first flip-flop when set;
a delay circuit connected between an output terminal of the second flip-flop and a reset terminal of the first flip-flop;
a first set signal output unit for outputting a set signal which sets the first flip-flop in response to a detection of a change of the differential signal from the low level to the high level;
a second set signal output unit for outputting a set signal which sets the second flip-flop in response to a detection that the inter-line switching element has turned on; and
an ON setting unit for enabling a conduction control terminal of the inter-line switching element to be turned to an ON level, when the first flip-flop is set.

4. The ringing suppression circuit according to claim 3, wherein the continuous activation prevention unit includes:
a third flip-flop which is reset in the initial state and outputs a mask signal setting the mask time period when set in correspondence to setting of the second flip-flop;
a reset signal generation unit for resetting the third flip-flop when a time period corresponding to the mask time period elapses from time of setting of the third flip-flop; and
a logic gate for invalidating the set signal for setting the first flip-flop by the mask signal.

5. The ringing suppression circuit according to claim 4, wherein:
the logic gate is connected between the first set signal output unit and the first flip-flop.

6. The ringing suppression circuit according to claim 4, wherein:
the logic gate is provided at a preceding stage of the first set signal output unit.

7. The ringing suppression circuit according to claim 3, wherein the continuous activation prevention unit includes:
a third flip-flop which is reset in the initial state and outputs a mask signal setting the mask time period when set in correspondence to setting of the first flip-flop;
a reset signal generation unit for resetting the third flip-flop when a time period corresponding to the mask time period elapses from time of setting of the mask flip-flop; and
a logic gate for invalidating the set signal setting the first flip-flop by the mask signal.

8. The ringing suppression circuit according to claim 3, wherein:
the second set signal output unit includes:
a detection switching element having a non-potential reference side conduction terminal connected to a power source via a resistance element, and a potential reference side conduction terminal and a conduction control terminal connected to a potential reference side conduction terminal and a conduction control terminal of the inter-line switching element, respectively; and
the ON setting unit includes:
first to fourth switching elements having potential reference side conduction terminals connected to the potential reference side conduction terminal of the inter-line switching element, respectively;
a fifth switching element having a potential reference side conduction terminal connected to the power source and a non-potential reference side conduction terminal connected to a non-potential reference side conduction terminal of the second switching element and the conduction control terminal of the third switching element via a resistance element; and
a sixth switching element having a potential reference side conduction terminal connected to the power source and a non-potential reference side conduction terminal connected to a non-potential reference side conduction terminal of the third switching element and the conduction control terminal of the inter-line switching element via a resistance element,
a conduction control terminal of the first switching element is connected to the conduction control terminal of the inter-line switching element;
conduction control terminals of the second and fourth switching elements are connected to a non-potential reference side conduction terminal of the first switching element and further connected via a resistance element to the non-potential reference side conduction terminal of the inter-line switching element;
a conduction control terminal of the third switching element is connected to a non-potential reference side conduction terminal of the second switching element; and
the fifth and sixth switching elements are configured to turn on and off when the first flip-flop is set, respectively.

9. The ringing suppression circuit according to claim 1, further comprising:
a detection mask unit for masking a detection of the change of the differential signal by the control unit for a predetermined time period in respON seto the detection of the change of the differential signal from the low level to the high level.

10. The ringing suppression circuit according to claim 4, further comprising:
a detection mask unit for masking a detection of the change of the differential signal by the control unit for a predetermined time period in respON seto the detection of the change of the differential signal from the low level to the high level.

11. The ringing suppression circuit according to claim 10, wherein:
the detection mask unit includes a delay circuit for delaying the set signal output from the first set signal output unit to the first flip-flop.

12. The ringing suppression circuit according to claim 9, wherein:
the continuous activation prevention unit sets the end time to be at least 1-bit length of a signal data and less than {(2-bit length)−(the predetermine time period)} from time of the change of the differential signal from the high level to the low level.
